(19) United States
(12) Patent Application Publication
(10) Pub. No.: US 2004/0150062 A1
(43) Pub. Date: Aug. 5, 2004

(54) Simplified image sensor module

(76) Inventors: Jackson Hsieh, Hsinchu Hsien (TW); Jichen Wu, Hsinchu Hsien (TW); Bruce Chen, Hsinchu Hsien (TW); Kuo-Tai Tseng, Hsinchu Hsien (TW)

Correspondence Address: PRO-TECHTOR INTERNATIONAL, 20775 Norada Court, Saratoga, CA, 95070-3018, US

(21) Appl. No.: 10/358,501

(22) Filed: Feb. 4, 2003

(51) Int. Cl. H01L 31/0203

(52) U.S. Cl. 257/433

(57) ABSTRACT

A simplified image sensor module of the invention includes a substrate, a frame layer, a photosensitive chip, wires, and a transparent layer. The substrate has an upper surface and a lower surface. The frame layer has a first surface and a second surface. The first surface is arranged on the upper surface of the substrate, and a cavity is formed between the substrate and the frame layer. The photosensitive chip has bonding pads and is mounted to the upper surface of the substrate and located within the cavity. The wires electrically connect the bonding pads of the photosensitive chip to the substrate. The transparent layer is arranged on the second surface of the frame layer and is formed with a convex portion at a position corresponding to the photosensitive chip. Accordingly, the photosensitive chip may receive focused optical signals passing through the convex portion.

### BACKGROUND OF THE INVENTION

1. Field of the Invention

The invention relates to a simplified image sensor module, and in particular to an image sensor module having a simplified structure that may be manufactured easily and in low cost.

2. Description of the Related Art

Referring to FIG. 1, a conventional image sensor module includes a lens holder 10, a lens barrel 20, and an image sensor 30. The lens holder 10 has a top face 12, a bottom face 14 and a chamber 16 penetrating through the lens holder 10 from the top face 12 to the bottom face 14. The chamber 16 of the lens holder 10 is formed with an internal thread 18. The lens barrel 20 is formed with an external thread 22, inserted into the chamber 16 from the top face 12 of the lens holder 10, and screwed to the internal thread 18 of the lens holder 10. The lens barrel 20 is also formed with a transparent region 24. An aspheric lens 26 is arranged within the chamber 16 and under the transparent region 24. An infrared filter 28 is also arranged within the chamber and under the aspheric lens 26. The image sensor 30 has a first face 32 and a second face 34. The first face 32 is provided with a transparent layer 36. The transparent layer 36 of the image sensor 30 is adhered to the bottom face 14 of the lens holder 10. The focal length between the aspheric lens 26 of the lens barrel 20 and the transparent layer 36 of the image sensor 30 may be controlled by adjusting the screwed length between the lens barrel 20 and the lens holder 10.

However, the above-mentioned image sensor module has the following drawbacks.

1. The manufacturing processes are complicated because the image sensor 30 has to be packaged and then combined with the lens holder 10 and the lens barrel 20 to form a module so that the image sensor 30 may receive optical signals focused by the aspheric lens 26. Therefore, the structure of the image sensor module is complicated and the overall volume thereof is large.

2. Since the transparent layer 36 is adhered to the bottom face 14 of the lens holder 10 by an adhesive, the adhesive may contaminate the surface of the transparent layer 36 and the image sensor cannot receive optical signals normally.

3. When the module is assembled, the transparent layer 36 has to be precisely aligned with the aspheric lens 26 and then adhered to the aspheric lens 26. After the-adhering process, if the transparent layer 36 and the aspheric lens 26 are not aligned properly, the overall module cannot be disassembled and reassembled, and the module has to be treated as a waste material.

### SUMMARY OF THE INVENTION

An object of the invention is to provide a simplified image sensor module having a simplified structure that may be manufactured easily and in low cost.

Another object of the invention is to provide a simplified image sensor module having a miniaturized volume.

To achieve the above-mentioned objects, the invention provides a simplified image sensor module including a substrate, a frame layer, a photosensitive chip, wires, and a transparent layer. The substrate has an upper surface and a lower surface. The frame layer has a first surface and a second surface. The first surface is arranged on the upper surface of the substrate, and a cavity is formed between the substrate and the frame layer. The photosensitive chip has bonding pads and is mounted to the upper surface of the substrate and located within the cavity. The wires electrically connect the bonding pads of the photosensitive chip to the substrate. The transparent layer is arranged on the second surface of the frame layer and is formed with a convex portion at a position corresponding to the photosensitive chip.

Accordingly, the photosensitive chip may receive focused optical signals passing through the convex portion.

### BRIEF DESCRIPTION OF THE DRAWINGS

FIG. 1 is a cross-sectional view showing a conventional image sensor module.

FIG. 2 is an exploded, cross-sectional view showing a simplified image sensor module of the invention.

FIG. 3 is a cross-sectional view showing the simplified image sensor module of the invention.

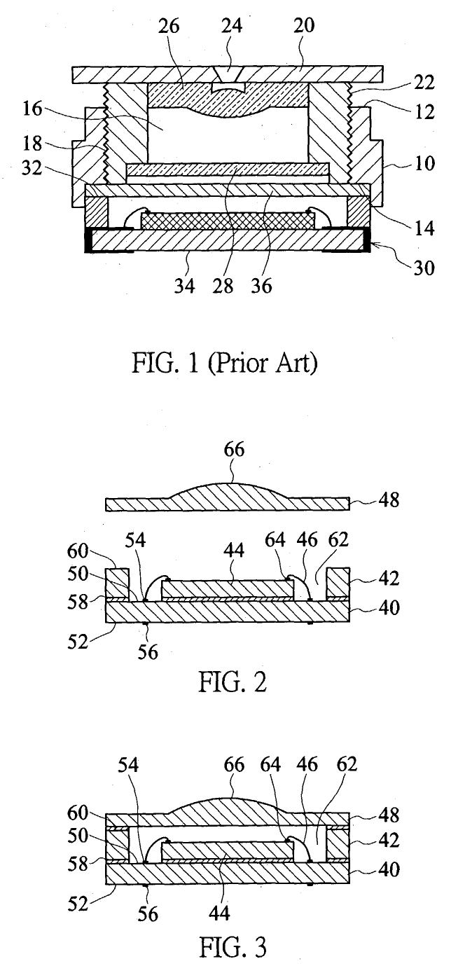

### DETAILED DESCRIPTION OF THE INVENTION

Referring to FIG. 2, a simplified image sensor module of the invention includes a substrate 40, a frame layer 42, a photosensitive chip 44, a plurality of wires 46 and a transparent layer 48.

The substrate 40 has an upper surface 50 on which a plurality of first connection points 54 is formed, and a lower surface 52 on which a plurality of second connection points 56 is formed for being electrically connected to a printed circuit board.

The frame layer 42 has a first surface 58 and a second surface 60. The first surface 58 of the frame layer 42 is placed on the upper surface 50 of the substrate 40 to form a cavity 62 together with the substrate 40.

The photosensitive chip 44 is formed with a plurality of bonding pads 64, mounted to the upper surface 50 of the substrate 40, and located within the cavity 62.

The wires 46 electrically connect the bonding pads 64 of the photosensitive chip 44 to the first connection points 54 of the substrate 40, respectively, so as to transfer signals from the photosensitive chip 44 to the substrate 40.

The transparent layer 48 is a piece of transparent glass placed on the second surface 60 of the frame layer 42. The transparent layer 48 is formed with a convex portion 66 at a position corresponding to the photosensitive chip 44. The convex portion 66 has an arc shape to provide a focus function and the photosensitive chip 44 may receive optical signals passing through and focused by the convex portion 66.

Please refer to FIG. 3. When the image sensor module of the invention is manufactured, the first surface 58 of the frame layer 42 is adhered to the upper surface 50 of the substrate 40 and then the cavity 62 is formed between the substrate 40 and the frame layer 42. Next, the photosensitive chip 44 is mounted to the upper surface 50 of the substrate 40 and located within the cavity 62. Then, the plurality of wires 46 is provided to electrically connect the photosensitive chip 44 to the first connection points 54 of the substrate 40. Finally, the transparent layer 48 having the convex portion 66 is placed on and adhered to the second surface 60 of the frame layer 42 to cover over the photosensitive chip 44. In this case, the convex portion 66 of the transparent layer 48 is exactly located at a position corresponding to the photosensitive chip 44 so that the photosensitive chip 44 may receive the focused optical signals passing through the convex portion 66.

After the photosensitive chip 44 is packaged, it can receive the focused optical signals passing through the convex portion 66 of the transparent layer 48. Therefore, no optical module has to be added to the image sensor, the product volume can be effectively reduced, the manufacturing processes may be simplified, and the manufacturing cost may be effectively reduced.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. A simplified image sensor module, comprising:
a substrate having an upper surface and a lower surface;
a frame layer having a first surface and a second surface, the first surface being arranged on the upper surface of the substrate, and a cavity being formed between the substrate and the frame layer;
a photosensitive chip having a plurality of bonding pads, the photosensitive chip being mounted to the upper surface of the substrate and located within the cavity;
a plurality of wires for electrically connecting the bonding pads of the photosensitive chip to the substrate; and
a transparent layer arranged on the second surface of the frame layer, the transparent layer being formed with a convex portion at a position corresponding to the photosensitive chip.

2. The simplified image sensor module according to claim 1, wherein the upper surface of the substrate is formed with a plurality of first connection points, and the wires electrically connect the bonding pads of the photosensitive chip to the first connection points, respectively.

3. The simplified image sensor module according to claim 1, wherein the lower surface of the substrate is formed with a plurality of second connection points.

4. The simplified image sensor module according to claim 1, wherein the convex portion of the transparent layer has an arc shape.

5. The simplified image sensor module according to claim 1, wherein the transparent layer is a piece of transparent glass.
